(19) United States
(12) Patent Application Publication
(10) Pub. No.: US 2018/0102776 A1
(43) Pub. Date: Apr. 12, 2018

(54) METHODS AND APPARATUS FOR MANAGING APPLICATION-SPECIFIC POWER GATING ON MULTICHIP PACKAGES

(71) Applicant: Altera Corporation, San Jose, CA (US)

(72) Inventors: Karthik Chandrasekar, Fremont, CA (US); Chee Hak Teh, Bayan Lepas (MY)

(21) Appl. No.: 15/288,927

(22) Filed: Oct. 7, 2016

(51) Int. Cl. H03K 17/687; H01L 23/498; H01L 23/00; H01L 25/18

(52) U.S. Cl. CPC H03K 17/6872; H01L 23/49838; H01L 24/16; H01L 2924/1434; H01L 2224/16227; H01L 2924/1433; H01L 25/18

(57) ABSTRACT

A multichip package is provided that includes multiple integrated circuit (IC) dies mounted on a shared interposer. The IC dies may communicate with one another via corresponding input-output (IO) elements on the dies. The interposer may include a system-level power management block that is configured to coordinate low-power entry and exit for the IO elements based on customer application needs. Performing application-specific power gating, which may include a combination of coarse-grained and fine-grained power gating control of the IO elements while the IO interface is sitting idle, can help maximize power savings in memory and a variety of other user applications.

### BACKGROUND

This relates generally to integrated circuit packages and more particularly, to methods for reducing power consumption on integrated circuit packages.

An integrated circuit package typically includes an integrated circuit die and a substrate on which the die is mounted. The die is often coupled to the substrate through bonding wires or solder bumps. Signals from the integrated circuit die may then travel through the bonding wires or solder bumps to the substrate.

As integrated circuit technology scales towards smaller device dimensions, device performance continues to improve at the expense of increased power consumption. In an effort to reduce power consumption, more than one die may be placed within a single integrated circuit package (i.e., a multi-chip package). As different types of devices cater to different types of applications, more dies may be required in some systems to meet the requirements of high performance applications. Accordingly, to obtain better performance and higher density, an integrated circuit package may include multiple dies arranged laterally along the same plane or may include multiple dies stacked on top of one another.

Power consumption is a critical challenge for modern integrated circuits. Circuits with poor power efficiency place undesirable demands on system designers. Power supply capacity may need to be increased, thermal management issues may need to be addressed, and circuit designs may need to be altered to accommodate inefficient circuitry.

A multi-chip package can include multiple dies mounted on an interposer. The multiple dies can communicate with each other via in-package interconnects. In some arrangements, a primary integrated circuit processor may be coupled to multiple memory integrated circuit chips via interconnects formed in the interposer. Although the interconnect power is substantially lower for in-package memory components compared to traditional off-package memory, the explosion of transistor count per unit area is driving up power consumption. For example, double data rate (DDR) and serializer/deserializer (SerDes) input-output interfaces can still consume a significant amount of power in a multi-chip package.

It is within this context that the embodiments described herein arise.

### SUMMARY

A multichip integrated circuit (IC) package may be provided with a system-level power gating scheme. The multichip package may include a package substrate, an interposer mounted on the package substrate, and at least first and second IC dies mounted on the interposer. The first die may include an input-output (IO) element that is used to communicate with the second die via an interface that is at least partially formed through the interposer.

In accordance with an embodiment, the interposer may include application-specific power gating circuitry that dynamically powers down the input-output element on the first die in response to determining that at least part of the interface will be temporarily idle. For example, in the scenario in which the second die is a memory chip, the power gating circuitry may be configured to perform coarse-grained power gating in response to determining that all channels in the interface will be idle during a self-refresh mode of the memory chip and may further be configured to perform fine-grained power gating in response to determining that only a subset of channels in the interface will be idle during the self-refresh mode.

This is merely illustrative. In general, the on-interposer power gating circuitry may be configured to power down at least a portion of the first die whenever any given application running on the second die is temporarily in a lower power mode or is temporarily idle. The power gating circuitry may also be implemented using a relatively less advanced processing technology compared to that used to implement the first and second dies to help save cost. Configured in this way, power savings may be optimized on a system-level.

Further features of the invention, its nature and various advantages will be more apparent from the accompanying drawings and following detailed description.

### BRIEF DESCRIPTION OF THE DRAWINGS

FIG. 1 is a diagram of an illustrative programmable integrated circuit in accordance with an embodiment.

FIG. 2 is a diagram of an illustrative multichip package in accordance with an embodiment.

FIG. 3 is a cross-sectional side view of a multichip package with multiple dies stacked on a shared interposer in accordance with an embodiment.

FIGS. 4A-4C show various illustrative power gating schemes in accordance with an embodiment.

FIG. 5 is a diagram showing how power gating circuitry on a multichip interposer may be operated in a static power gating mode or a dynamic power gating mode with adjustable granularity in accordance with an embodiment.

FIG. 6 is a flow chart of illustrative steps for performing application-specific power gating operations on a multichip package in accordance with an embodiment.

### DETAILED DESCRIPTION

The embodiments presented herein relate to integrated circuit packages and, more particularly, to multichip packages.

It will be recognized by one skilled in the art, that the present exemplary embodiments may be practiced without some or all of these specific details. In other instances, well-known operations have not been described in detail in order not to unnecessarily obscure the present embodiments.

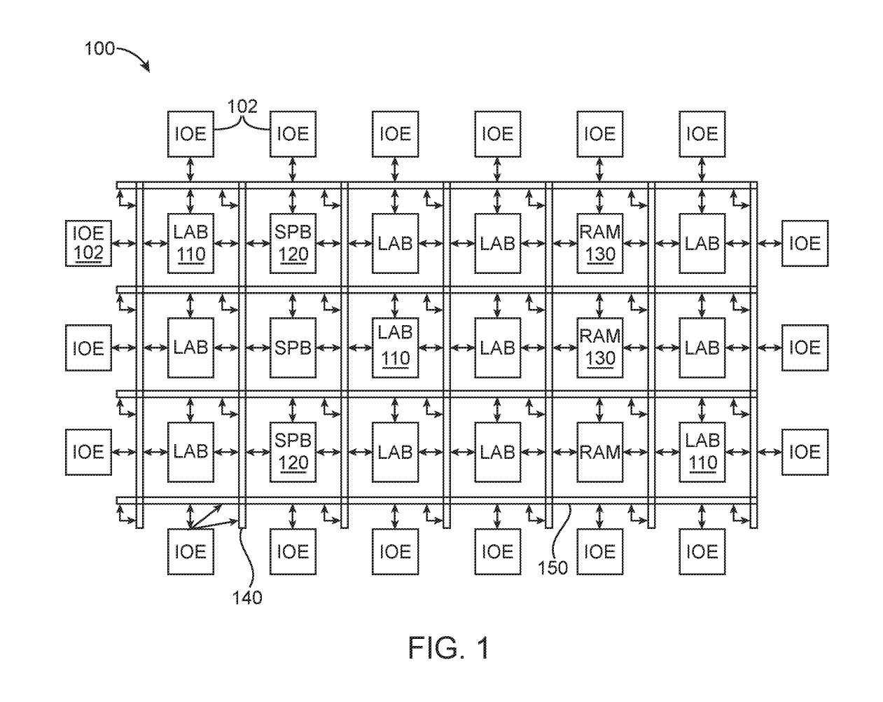

An illustrative embodiment of an integrated circuit such as programmable logic device (PLD) 100 having an exemplary interconnect circuitry is shown in FIG. 1. As shown in FIG. 1, the programmable logic device (PLD) may include a two-dimensional array of functional blocks, including logic array blocks (LABs) 110 and other functional blocks, such as random access memory (RAM) blocks 130 and specialized processing blocks such as specialized processing blocks (SPB) 120. Functional blocks such as LABs 110 may include smaller programmable regions (e.g., logic elements, configurable logic blocks, or adaptive logic modules) that receive input signals and perform custom functions on the input signals to produce output signals.

Programmable logic device 100 may contain programmable memory elements. Memory elements may be loaded with configuration data (also called programming data) using input/output elements (IOEs) 102. Once loaded, the memory elements each provide a corresponding static control signal that controls the operation of an associated functional block (e.g., LABs 110, SPB 120, RAM 130, or input/output elements 102).

In a typical scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, etc.

The memory elements may use any suitable volatile and/or non-volatile memory structures such as random-access-memory (RAM) cells, fuses, antifuses, programmable read-only-memory memory cells, mask-programmed and laser-programmed structures, mechanical memory devices (e.g., including localized mechanical resonators), mechanically operated RAM (MORAM), combinations of these structures, etc. Because the memory elements are loaded with configuration data during programming, the memory elements are sometimes referred to as configuration memory, configuration RAM (CRAM), configuration memory elements, or programmable memory elements.

In addition, the programmable logic device may have input/output elements (IOEs) 102 for driving signals off of device 100 and for receiving signals from other devices. Input/output elements 102 may include parallel input/output circuitry, serial data transceiver circuitry, differential receiver and transmitter circuitry, or other circuitry used to connect one integrated circuit to another integrated circuit. As shown, input/output elements 102 may be located around the periphery of the chip. If desired, the programmable logic device may have input/output elements 102 arranged in different ways. For example, input/output elements 102 may form one or more columns of input/output elements that may be located anywhere on the programmable logic device (e.g., distributed evenly across the width of the PLD). If desired, input/output elements 102 may form one or more rows of input/output elements (e.g., distributed across the height of the PLD). Alternatively, input/output elements 102 may form islands of input/output elements that may be distributed over the surface of the PLD or clustered in selected areas.

The PLD may also include programmable interconnect circuitry in the form of vertical routing channels 140 (i.e., interconnects formed along a vertical axis of PLD 100) and horizontal routing channels 150 (i.e., interconnects formed along a horizontal axis of PLD 100), each routing channel including at least one track to route at least one wire. If desired, the interconnect circuitry may include double data rate interconnections and/or single data rate interconnections.

If desired, routing wires may be shorter than the entire length of the routing channel. A length L wire may span L functional blocks. For example, a length four wire may span four blocks. Length four wires in a horizontal routing channel may be referred to as “H4” wires, whereas length four wires in a vertical routing channel may be referred to as “V4” wires.

Different PLDs may have different functional blocks which connect to different numbers of routing channels. A three-sided routing architecture is depicted in FIG. 1 where input and output connections are present on three sides of each functional block to the routing channels. Other routing architectures are also intended to be included within the scope of the present invention. Examples of other routing architectures include 1-sided, 1½-sided, 2-sided, and 4-sided routing architectures.

In a direct drive routing architecture, each wire is driven at a single logical point by a driver. The driver may be associated with a multiplexer which selects a signal to drive on the wire. In the case of channels with a fixed number of wires along their length, a driver may be placed at each starting point of a wire.

Note that other routing topologies, besides the topology of the interconnect circuitry depicted in FIG. 1, are intended to be included within the scope of the present invention. For example, the routing topology may include diagonal wires, horizontal wires, and vertical wires along different parts of their extent as well as wires that are perpendicular to the device plane in the case of three dimensional integrated circuits, and the driver of a wire may be located at a different point than one end of a wire. The routing topology may include global wires that span substantially all of PLD 100, fractional global wires such as wires that span part of PLD 100, staggered wires of a particular length, smaller local wires, or any other suitable interconnection resource arrangement.

Furthermore, it should be understood that embodiments may be implemented in any integrated circuit. If desired, the functional blocks of such an integrated circuit may be arranged in more levels or layers in which multiple functional blocks are interconnected to form still larger blocks. Other device arrangements may use functional blocks that are not arranged in rows and columns.

As integrated circuit fabrication technology scales towards smaller process nodes, it becomes increasingly challenging to design an entire system on a single integrated circuit die (sometimes referred to as a system-on-chip). Designing analog and digital circuitry to support desired performance levels while minimizing leakage and power consumption can be extremely time consuming and costly.

One alternative to single-die packages is an arrangement in which multiple dies are placed within a single package. Such types of packages that contain multiple interconnected dies may sometimes be referred to as systems-in-package (SiPs), multichip modules (MCM), or multichip packages. Placing multiple chips (dies) into a single package may allow each die to be implemented using the most appropriate technology process (e.g., a memory chip may be implemented using the 14 nm technology node, whereas the radio-frequency analog chip may be implemented using the 90 nm technology node), may increase the performance of die-to-die interface (e.g., driving signals from one die to another within a single package is substantially easier than driving signals from one package to another, thereby reducing power consumption of associated input-output buffers), may free up input-output pins (e.g., input-output pins associated with die-to-die connections are much smaller than pins associated with package-to-board connections), and may help simplify printed circuit board (PCB) design (i.e., the design of the PCB on which the multichip package is mounted during normal system operation).

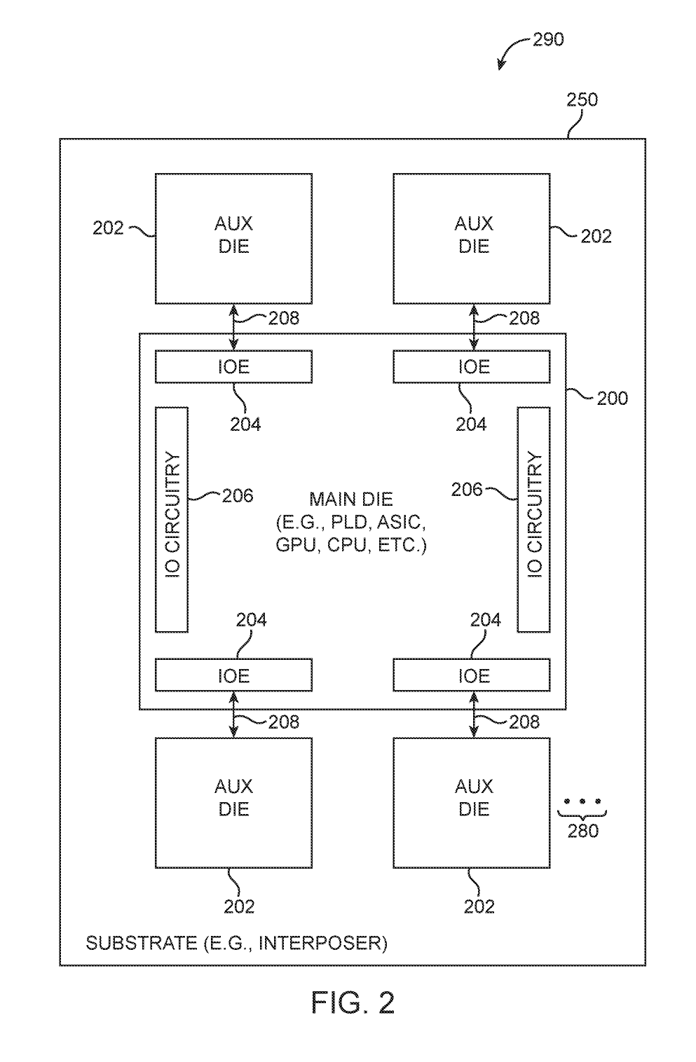

FIG. 2 shows one suitable arrangement of a multichip package such as package 290. As shown in FIG. 2, package 290 may include an integrated circuit 200 that is coupled to multiple auxiliary integrated circuit devices 202. Die 200, which may be a central processing unit (CPU), a graphics processing unit (GPU), an application-specific integrated circuit (ASIC), a programmable device, or other suitable integrated circuit, may serve as a primary processor for package 290 and may therefore sometimes be referred to herein as the main die. The auxiliary components 202 that communicate with the main die are sometimes referred to as “daughter” dies. Main die 200 and the daughter dies 202 may be mounted on a common substrate such as interposer 250.

Integrated circuit 200 may include input-output circuitry 206 for interfacing with devices external to package 290. Main integrated circuit 200 may also include physical-layer (PHY) interface circuitry such as input-output elements 204 that serve to communicate with the auxiliary components 202 via in-package communications paths 208.

In accordance with some embodiments, each auxiliary component 202 may be a memory chip stack (e.g., one or more memory devices stacked on top of one another) that is implemented using random-access memory such as static random-access memory (SRAM), dynamic random-access memory (DRAM), low latency DRAM (LLDRAM), reduced latency DRAM (RLDRAM) or other types of volatile memory. If desired, each auxiliary memory chip stack 202 may also be implemented using nonvolatile memory (e.g., fuse-based memory, antifuse-based memory, electrically-programmable read-only memory, etc.). Each auxiliary component 202 that serves as a memory chip stack is sometimes referred to herein as a “memory element.”

Each circuit 204 may serve as a physical-layer bridging interface between an associated memory controller on main die 200 (e.g., a non-reconfigurable “hard” memory controller or a reconfigurable “soft” memory controller logic) and one or more high-bandwidth channels that is coupled to an associated memory element 202. For example, each instantiation of the PHY interface circuit 204 can be used to support multiple parallel channel interfaces such as the JEDEC JESD235 High Bandwidth Memory (HBM) DRAM interface or the Quad Data Rate (QDR) wide IO SRAM interface (as examples). Each of the parallel channels can support single data rate (SDR) or double data rate (DDR) communications.

The examples described above in which auxiliary die 202 is a memory element are merely illustrative and are not intended to limit the scope of the present embodiments. If desired, PHY circuit 204 may also be used to support a wide array of channel interfaces including but not limited to: high speed transceiver IO interface, Peripheral Component Interconnect Express (PCIe) interface, Serializer/Deserializer (SerDes) interface, Industry-Standard Architecture (ISA) interface, Small Computer Systems Interface (SCSI), Serial ATA interface, and/or other suitable types of computer bus standard. Different IO interfaces consume different amounts of power. For certain applications that consume more power, it may be desirable to provide a way of selectively powering down the interface at opportune times to help minimize power consumption.

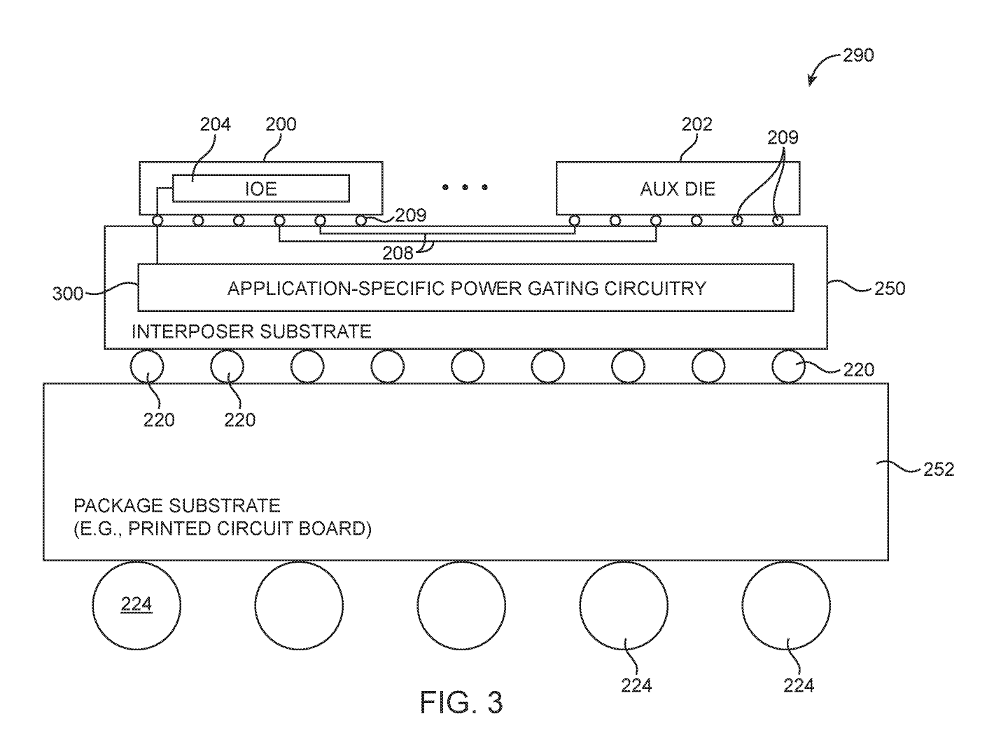

FIG. 3 is a cross-sectional side view of an illustrative multichip package 290. As shown in FIG. 3, multichip package 290 may include a package substrate such as package substrate 252, interposer 250 that is mounted on top of package substrate 252, and multiple dies mounted on top of interposer 250 (e.g., dies 200 and 202 may be mounted laterally with respect to each other on top of interposer 250).

Package substrate 252 may be coupled to a board substrate (e.g., a printed circuit board on which multichip package 290 is mounted) via solder balls 224. As an example, solder balls 224 may form a ball grid array (BGA) configuration for interfacing with corresponding conductive pads on the printed circuit board (PCB). The exemplary configuration of FIG. 3 in which two laterally positioned dies are interconnected via an interposer carrier structure 250 may sometimes be referred to as 2.5-dimensional (“2.5D”) stacking. If desired, more than two laterally (horizontally) positioned dies may be mounted on top of interposer structure 250. In other suitable arrangements, multiple dies may be stacked vertically on top of one another. In general, multichip package 290 may include any number of dies stacked on top of one another and dies arranged laterally with respect to one another.

Dies 200 and 202 may be electrically coupled to interposer 250 via microbumps 209. Microbumps 209 may refer to solder bumps that are formed on the top layer of dies 200 and 202 and may each have a diameter of 10 μm (as an example). In particular, microbumps 209 may be deposited on microbump pads that are formed in the uppermost layer of a dielectric interconnect stack in each of die 200 and 202.

Interposer 250 may be coupled to package substrate 252 via bumps 220. Bumps 220 that interface directly with package substrate 252 may sometimes be referred to as controlled collapse chip connection (C4) bumps or “flip-chip” bumps and may each have a diameter of 100 μm (as an example). Generally, flip-chip bumps 220 (e.g., bumps used for interfacing with off-package components) are substantially larger in size compared to microbumps 209 (e.g., bumps used for interfacing with other dies within the same package). The number of microbumps 209 is typically much greater than the number of flip-chip bumps 220 (e.g., the ratio of the number of microbumps to the number of flip-chip bumps may be greater than 2:1, 5:1, 10:1, etc.).

In one suitable arrangement, interposer 250 may be formed from silicon. Interposer 250 of this type may include circuitry such as interposer routing circuitry 208 that can be used for conveying signals between dies 200 and 202. The dies that are mounted on interposer 250 within multichip package 290 are sometimes referred to as “on-interposer” or “on-package” devices.

As described above, the IO elements for on-package dies can sometimes consume a substantial amount of power. This problem is exacerbated as bandwidth requirements and transistor density continues to increase with industry demand. For example, while a low power DDR2 IO operation might consume only 500 pico-Joules per data word transfer (pJ/word), a high speed SerDes IO operation could consume up to 2 nJ/word, whereas a DDR3 IO operation could consume up to 5 nJ/word, which are orders of magnitudes greater than the typical IO operation.

In order to ameliorate this problem, multichip package 290 may be provided with power management circuitry such as application-specific power gating circuitry 300 in interposer 250. While the cost for implementing dedicated power gating circuitry on the integrated circuit dies themselves is high, forming power gating circuitry instead on the interposer provides a more cost-effective way to add power gating features to the multichip package without actually increasing die-level area. Moreover, circuitry on the interposer may be implemented using an older process node, which can further reduce cost overhead. For instance, while dies 200 and 202 might be implemented at the most advanced processing node such as at the 14 nm technology node, interposer 250 can be implemented using a relatively older and cheaper processing node such as at the 90 nm technology node.

In particular, power gating circuitry 300 may be a system level power management block that regulates the total system power by selectively powering down one or more IO elements in the 2.5 D arrangement. For example, power gating circuitry 300 may be aware when a particular IO element 204 on die 200 will be idle (e.g., circuitry 300 will know when IO element 204 is not actively communicating with daughter die 202) and will therefore selectively adjust the power that is provided to IO element 204 based on its current requirements. If desired, power gating circuitry 300 may simply power down the IO element 204 completely during the down time or may instead tune the power level to some intermediate level if the full bandwidth is not required. In other words, power gating circuitry 300 may be configured to dynamically adjust the power that is provided to each IO element within an on-interposer die depending on the needs of the specific application currently being run or supported. If desired, only the corresponding IO elements 204 on the main die and/or the daughter die will be powered off during power gating operations.

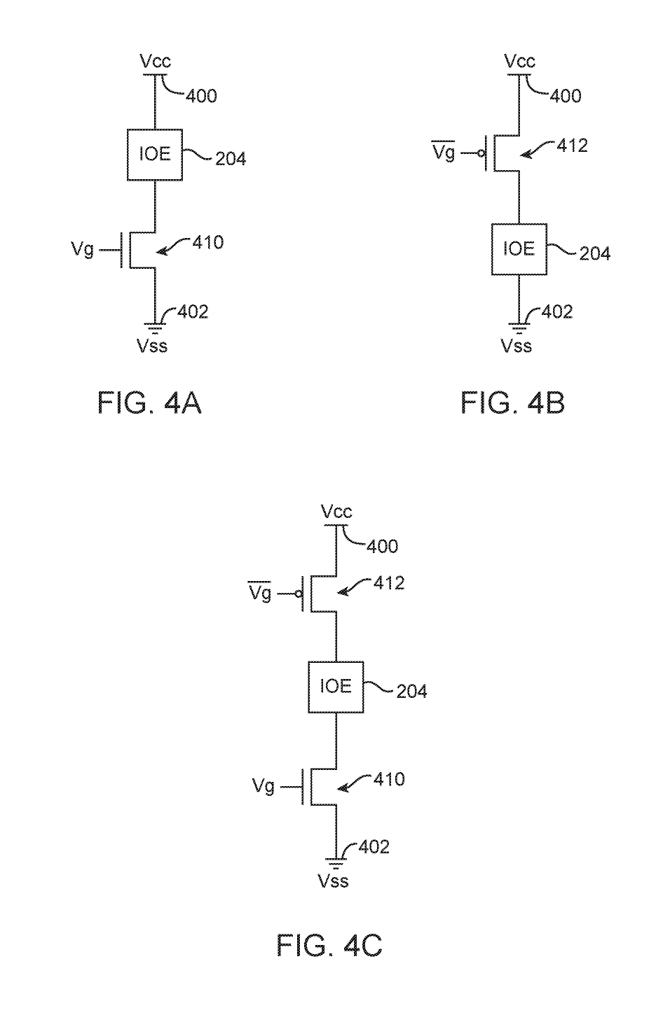

FIGS. 4A-4C show various illustrative power gating schemes that can be implemented on the interposer. FIG. 4A shows how a pull-down transistor such as n-channel transistor 410 may be coupled in series with IO element 204 between positive power supply line 400 (e.g., a power supply line on which positive power supply voltage Vcc is provided) and ground power supply line 402 (e.g., a power supply line on which ground voltage Vss is provided). IO element 204 is formed within one of the on-interposer dies, whereas transistor 410 is formed as part of the power gating circuitry within the interposer. Control signal Vg may control when power gating is activated. For example, signal Vg may be asserted (e.g., driven high) to allow IO element 204 to functional normally as intended or may be deasserted (e.g., driven low) to power down IO element 204.

FIG. 4B shows another suitable arrangement where a pull-up transistor such as p-channel transistor 412 is coupled in series with IO element 204 between positive power supply line 400 and ground line 402. IO element 204 is formed within one of the on-interposer dies, whereas transistor 412 is formed as part of the power gating circuitry within the interposer. Transistor 412 may be controlled by active-low signal /Vg, which can be driven low to allow IO element 204 to function as intended or may be driven high to power off IO element 204.

FIG. 4C shows yet another suitable embodiment where power gating transistor 410 is added as a footer circuit for IO element 204 while power gating transistor 412 is added as a header circuit for IO element 204. IO element 204 shall be formed within one of the on-interposer dies, whereas transistors 410 and 412 may be formed as part of the power gating circuitry within the interposer. In general, transistors 410 and 412 may be high threshold voltage devices, which help to reduce leakage whenever power gating is activated (e.g., whenever transistors 410 and 412 are turned off to prevent current from flowing between power lines 400 and 402).

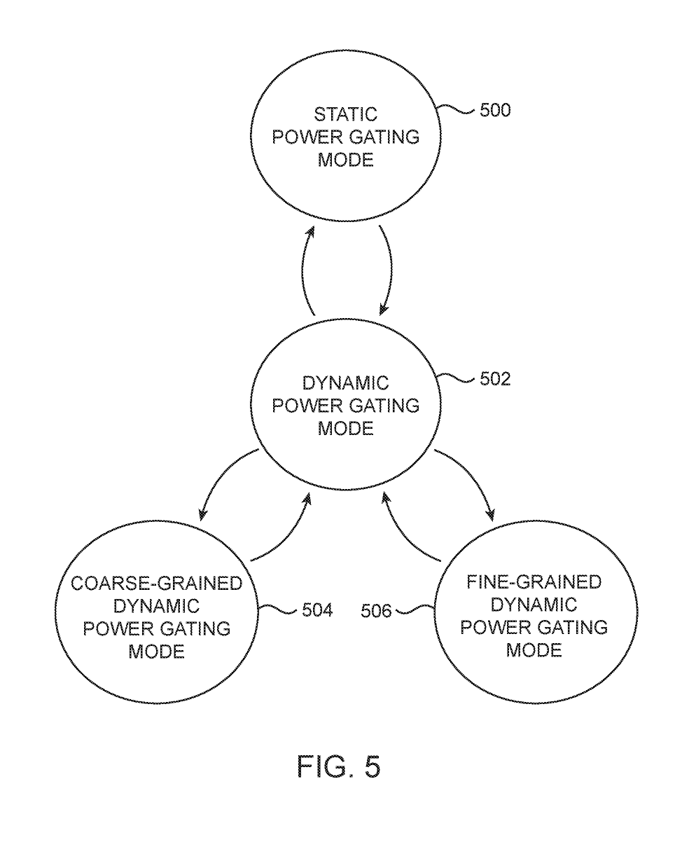

FIG. 5 is a diagram showing how a combination of fine grained and coarse grained power gating may be utilized to maximize power savings on a multichip package. If desired, a portion of the multichip package may be operated in a static power gating mode 500. As an example, if it is known that an auxiliary memory die is unused or not mapped in the currently running application(s), then the corresponding IO interface may be statically gated off.

In addition to static power gating mode 500, at least another portion of the multichip package may be operated in a dynamic power gating mode 502. During mode 502, the interposer may be dynamically gated during the low power states. For example, a high speed memory interface may be powered down when the memory enters self-refresh and may be powered up after the memory exits self-refresh.

In particular, dynamic coarse-grained power gating may be performed when all channels are in self-refresh (e.g., during power gating mode 504), whereas dynamic fine-grained power gating may be performed when only a selected subset of the memory channels is in self-refresh mode (e.g., when selected memory channel clusters enter self-refresh during power gating mode 506). To enable fine-grained power gating, the interposer may include dense power mesh circuitry having power isolation across individual IO channels, which is described in commonly-assigned application Ser. No. 14/554,667 filed Nov. 26, 2014, and is incorporated by reference in its entirety. In this particular example, the power saving/gating mode (sometimes referred to as a lower power mode) will terminate when the memory exits the self-refresh mode.

The example above in which dynamic power gating may be performed on a memory interface in a multichip package is merely illustrative and does not serve to limit the scope of the present embodiments. If desired, this dynamic power gating approach may be extended to various multi-die applications such as interfacing with applications-specific integrated circuit (ASIC) auxiliary dies. In particular, the power management circuitry on the interposer may be made aware when the interface to the ASIC die(s) will be idle and can therefore be gated off during those idle periods (e.g., the power management block may be configured to instruct the interposer to power gate the appropriate power rails on the system to selectively prevent idle IO interfaces from receiving a power supply voltage).

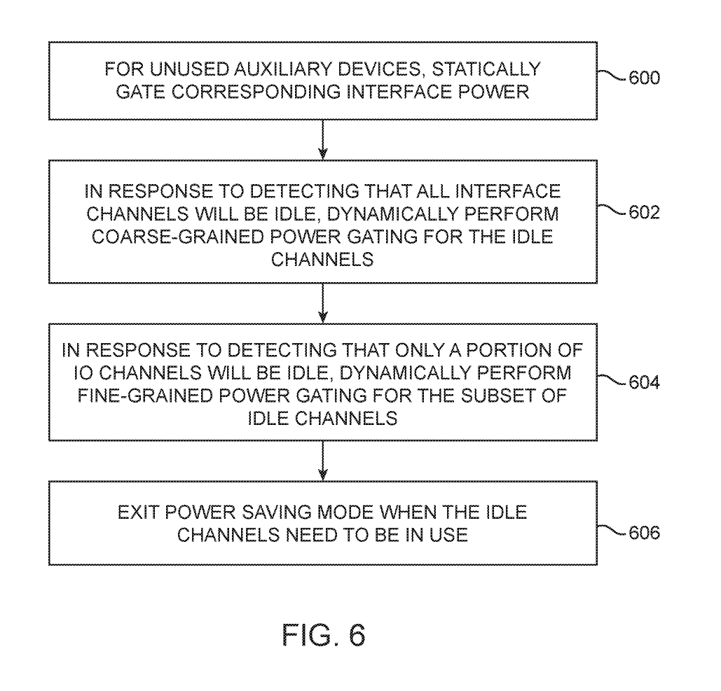

FIG. 6 is a flow chart of illustrative steps for performing application-specific power gating operations on a multichip package. At step 600, unused auxiliary devices on the multichip package may be statically gated off (e.g., the IO elements that communicate with unused daughter chips may be statically switched out of use).

At step 602, coarse-grained power gating operations may be performed in response to detecting that all interface channels for a particular auxiliary die will be idle. At step 604, fine-grained power gating operations may be performed in response to detecting that only a subset of interface channels for a given auxiliary die will be idle. If desired, coarse-grained power gating and fine-grained power gating may be dynamically performed for any given die within the multichip package depending on the particular application currently being supported (e.g., whenever a given application on an auxiliary die enters a power saving mode or a lower power mode).

At step 606, the power savings mode may exit when the idle channels need to be in use (e.g., power gating operations may terminate when the IO channels are no longer idle).

These steps are merely illustrative. The existing steps may be modified or omitted; some of the steps may be performed in parallel; additional steps may be added; and the order of certain steps may be reversed or altered. For example, in certain applications, only fine-grained power gating may be appropriate whereas only coarse-grained power gating might be sufficient in others. If desired, fine-grained power gating may be performed before coarse-grained power gating. In yet other suitable arrangements, static power gating may be omitted altogether.

The embodiments thus far have been described with respect to integrated circuits. The methods and apparatuses described herein may be incorporated into any suitable circuit. For example, they may be incorporated into numerous types of devices such as programmable logic devices, application specific standard products (ASSPs), and application specific integrated circuits (ASICs). Examples of programmable logic devices include programmable arrays logic (PALs), programmable logic arrays (PLAs), field programmable logic arrays (FPGAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The programmable logic device described in one or more embodiments herein may be part of a data processing system that includes one or more of the following components: a processor; memory; IO circuitry; and peripheral devices. The data processing can be used in a wide variety of applications, such as computer networking, data networking, instrumentation, video processing, digital signal processing, or any suitable other application where the advantage of using programmable or re-programmable logic is desirable. The programmable logic device can be used to perform a variety of different logic functions. For example, the programmable logic device can be configured as a processor or controller that works in cooperation with a system processor. The programmable logic device may also be used as an arbiter for arbitrating access to a shared resource in the data processing system. In yet another example, the programmable logic device can be configured as an interface between a processor and one of the other components in the system. In one embodiment, the programmable logic device may be one of the family of devices owned by ALTERA/INTEL Corporation.

The foregoing is merely illustrative of the principles of this invention and various modifications can be made by those skilled in the art. The foregoing embodiments may be implemented individually or in any combination.

What is claimed is:

1. An integrated circuit package, comprising:
an interposer;
a first die that is mounted on the interposer; and
a second die that is mounted on the interposer, wherein the interposer comprises:
an interface through which the first die communicates with the second die; and
power gating circuitry that dynamically powers down a portion of the first die while the interface is idle.

2. The integrated circuit package of claim 1, further comprising:
a package substrate on which the interposer is mounted.

3. The integrated circuit package of claim 1, wherein the portion of the first die that is dynamically powered down comprises an input-output element on the first die that directly interfaces with the second die.

4. The integrated circuit package of claim 1, wherein the power gating circuitry is further configured to statically power the interface in response to determining that the second die is unused.

5. The integrated circuit package of claim 1, wherein the power gating circuitry performs coarse-grained power gating in response to determining that all channels in the interface will be idle.

6. The integrated circuit package of claim 5, wherein the power gating circuitry further performs fine-grained power gating in response to determining that only a subset of the channels in the interface will be idle.

7. The integrated circuit package of claim 1, wherein the second die comprises a memory chip, and wherein the power gating circuitry temporarily powers down the portion of the first die while the memory chip is in a self-refresh mode.

8. The integrated circuit package of claim 1, wherein the first die comprises a programmable integrated circuit, wherein the second die comprises an application-specific integrated circuit, and wherein the power gating circuitry temporarily powers down the portion of the first die whenever an application running on the second die is temporarily idle.

9. A method of operating a multichip package, comprising:
sending data from a first die in the multichip package to a second die in the multichip package, wherein the first and second dies are mounted on an interposer within the multichip package;
relaying the data from the first die to the second die via an interface within the interposer; and
in response to detecting that at least a portion of the interface will be idle, selectively power gating the first die while the interface is idle using power management circuitry within the interposer.

10. The method of claim 9, wherein selectively power gating the first die comprises statically power gating an input-output element on the first die in response to determining that the second die is unused.

11. The method of claim 9, wherein selectively power gating the first die comprises dynamically power gating only input-output elements on the first die in response to determining that the second die is entering a power saving mode.

12. The method of claim 11, wherein dynamically power gating the input-output elements comprises performing coarse-grained power gating in response to determining that all channels of the interface will be idle during the power saving mode.

13. The method of claim 12, wherein dynamically power gating the input-output elements comprises performing fine-grained power gating in response to determining that only a subset of the channels in the interface will be idle during the power saving mode.

14. The method of claim 11, further comprising:
exiting the power saving mode before the interface resumes conveying data between the first and second dies across the interface.

15. The method of claim 11, wherein the second die comprises a memory die, and wherein dynamically power gating the input-output element comprises dynamically powering down the input-output elements right before the second die enters a self-refresh mode.

16. An apparatus, comprising:
a substrate;
a main die mounted on the substrate; and
an auxiliary die mounted on the substrate, wherein the auxiliary die communicates with the main die via an interface formed at least partially through the substrate, and wherein the substrate includes application-specific power management circuitry that dynamically power gates an input-output element on the main die in response to determining that an application on the auxiliary die is entering a lower power mode.

17. The apparatus of claim 16, wherein at least a portion of the interface is idle during the low power mode.

18. The apparatus of claim 16, wherein the application-specific power management circuitry is further configured to perform coarse-grained power gating and fine-grained power gating on the main die.

19. The apparatus of claim 16, wherein the main die is implemented using a first processing technology, and wherein the substrate is implemented using a second processing technology that is less advanced than the first processing technology.

20. The apparatus of claim 16, wherein the auxiliary die comprises a memory chip, and wherein the application-specific power management circuitry is further configured to power gate the input-output element in response to determining that the memory chip is entering a self-refresh mode.
